(19) United States
(12) Patent Application Publication
(10) Pub. No.: US 2011/0206862 A1
(43) Pub. Date: Aug. 25, 2011

(54) Titanium Nitride Film Deposition by Vapor Deposition Using Cyclopentadienyl Alkylamino Titanium Precursors

(75) Inventors: Julien Gatineau, Tsuchiura (JP); Changhee Ko, Tsukuba-shi (JP)

(73) Assignee: L'Air Liquide, Societe Anonyme pour I'Etude et I'Exploitation des Procedes Georges Claude, Pairs (FR)

(21) Appl. No.: 13/020,590

(22) Filed: Feb. 3, 2011

Related U.S. Application Data
(60) Provisional application No. 61/301,143, filed on Feb. 3, 2010.

(51) Int. Cl. C23C 16/34; C23C 16/50

(52) U.S. Cl. 427/569

(57) ABSTRACT

Disclosed are cyclopentadienyl alkylamino titanium precursors selected from the group consisting of Ti(iPr₃Cp)(NMe₂)₃, Ti(iPr₃Cp)(NEt₂)₃, Ti(iPr₃Cp)(NMeEt)₃, Ti(tBu₃Cp)(NMe₂)₃, Ti(tBu₃Cp)(NEt₂)₃, Ti(tBu₃Cp)(NMeEt)₃, Ti(Me₄EtCp)(NMe₂)₃, Ti(Me₄EtCp)(NEt₂)₃,

Ti(Me₄EtCp)(NMeEt)₃, Ti(Me₅Cp)(NMe₂)₃, Ti(Me₅Cp)(NEt₂)₃, and Ti(Me₅Cp)(NMeEt)₃ for use in vapor deposition methods, preferably PEALD or P-CVD, for the deposition of TiN films used in the manufacture of semiconductor, photovoltaic, LCD-TFT, or flat panel type devices.

### CROSS-REFERENCE TO RELATED APPLICATIONS

This application claims the benefit of U.S. Provisional Application No. 61/301,143, filed Feb. 3, 2010, the entire contents of which are incorporated herein by reference.

### BACKGROUND

Commercial depositions of TiN layers frequently use TiCl₄ as the titanium precursor. See, e.g., para 0022 US Pat App No 2010/193955. However, when chlorine-based precursors are used, chlorine-containing by-products (HCl, NH₄Cl . . . ) are released and their poor volatility or corrosive properties raise process-related issues. For example, high temperature processes are thus required.

JP2005171291 disclosed MOCVD deposition of TiN films using molecules of the general formula Ti(R³ₖCp)(NR¹R²)₃, wherein each R¹ and R² is a methyl (CH₃) or ethyl (C₂H₅) group, k is an integer from 1 to 5 when R³ is a C1-C4 alkyl group, k is an integer from 1 to 3 when R³ is a trimethylsilyl group, m is an integer 1 or 2, and n is an integer of 1 to 3. The only parameter reported for the resulting TiN film is final film thickness. No information regarding deposition rate, resistivity, or component analysis is provided for the resulting TiN film.

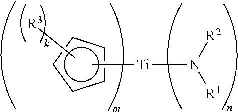

Ti(R³ₖCp)ₘ(NR¹R²)ₙ molecules as described in JP2005171291

WO2009036045 references JP2005171291 and discloses usage of the molecules for ALD of titanium oxide and nitride films. The preferred molecule is Ti(MeCp)(NMe₂)₃ and the use of this molecule is mentioned in ALD using hydrogen, hydrogen plasma, oxygen, air, water, ammonia, hydrazines, allylhydrazines, boranes, silanes, ozone, and a combination thereof However, the examples only disclose the growth rate and the SIMS analysis of TiO₂ films.

As the reaction mechanism to deposit nitride films differs from that used to deposit oxide films, the need remains to discover precursors suitable for nitride film deposition and produce nitride films having low resistivity and low impurity content.

### Notation and Nomenclature

Certain abbreviations, symbols, and terms are used throughout the following description and claims and include:

The term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “iPr” refers to an isopropyl group; the abbreviation “Bu” refers to a butyl group (n-butyl); the abbreviation “tBu” refers to tert-butyl; the abbreviation “sBu” refers to sec-butyl; the abbreviation “Cp” refers to cyclopentadienyl; and the abbreviation “Cp*” refers to pentamethylcyclopentadienyl.

### SUMMARY

Disclosed are vapor deposition methods for depositing a TiN film onto at least one substrate. A reactor having at least one substrate disposed therein is provided. The vapor of at least one titanium-containing precursor is introduced into the reactor. The titanium-containing precursor is selected from the group consisting of Ti(iPr₃Cp)(NMe₂)₃, Ti(iPr₃Cp)(NEt₂)₃, Ti(iPr₃Cp)(NMeEt)₃, Ti(tBu₃Cp)(NMe₂)₃, Ti(tBu₃Cp)(NEt₂)₃, Ti(tBu₃Cp)(NMeEt)₃, Ti(Me₄EtCp)(NMe₂)₃, Ti(Me₄EtCp)(NEt₂)₃, Ti(Me₄EtCp)(NMeEt)₃, Ti(Me₅Cp)(NMe₂)₃, Ti(Me₅Cp)(NEt₂)₃, and Ti(Me₅Cp)(NMeEt)₃. At least part of the titanium-containing precursor is deposited onto the substrate to form a titanium-containing layer on the substrate. The titanium-containing layer is reacted with the vapor of a plasma-treated reactant to form a TiN layer on the substrate. Optionally, the method may e repeated until the TiN film has the desired thickness. The method may further include one or more of the following aspects:
the plasma-treated reactants being reducing agents selected from the group consisting of N₂, NH₃, Si(NEt₂)₂H₂, N₂H₄, N(SiH₃)₃, NMeH₂, NEtH₂, NMe₂H, NEt₂H, NMe₃, NEt₃, (SiMe₃)₂NH, MeHNNH₂, Me₂NNH₂, phenyl hydrazine, and mixtures thereof;
the substrates having a temperature between approximately 50° C. and approximately 600° C.;
the reactor having a pressure between approximately 0.0001 Torr (0.0133 Pa) and approximately 1000 Torr (133.3 kPa);
the reactor being a direct plasma reactor;
the vapor of the plasma-treated reactants being produced by introducing a vapor of a reactant into the direct plasma reactor and exposing the vapor of the reactant to plasma to form the vapor of the plasma-treated reactant;
the titanium-containing precursors being selected from the group consisting of Ti(iPr₃Cp)(NMe₂)₃, Ti(iPr₃Cp)(NEt₂)₃, Ti(iPr₃Cp)(NMeEt)₃, and mixtures thereof;
the titanium-containing precursors being selected from the group consisting of Ti(Me₅Cp)(NMe₂)₃, Ti(Me₅Cp)(NEt₂)₃, Ti(Me₅Cp)(NMeEt)₃, and mixtures thereof;
the titanium-containing precursors being selected from the group consisting of Ti(tBu₃Cp)(NMe₂)₃, Ti(tBu₃Cp)(NEt₂)₃, Ti(tBu₃Cp)(NMeEt)₃, and mixtures thereof; and
the titanium-containing precursors being selected from the group consisting of Ti(Me₄EtCp)(NMe₂)₃, Ti(Me₄EtCp)(NEt₂)₃, Ti(Me₄EtCp)(NMeEt)₃, and mixtures thereof.

Also disclosed are vapor deposition methods for depositing a TiN film onto at least one substrate. A reactor having at least one substrate disposed therein is provided. The vapor of Ti(Me₅Cp)(NMe₂)₃ is introduced into the reactor. At least part of the Ti(Me₅Cp)(NMe₂)₃ is deposited onto the substrate to form a titanium-containing layer on the substrate. The titanium-containing layer is reacted with the vapor of plasma-treated NH₃ to form a TiN layer on the substrate. Optionally, the method may e repeated until the TiN film has the desired thickness. The method may further include one or more of the following aspects:
the reactor being a direct plasma reactor;
the vapor of plasma-treated NH₃ being produced by introducing a vapor of NH₃ into the direct plasma reactor and exposing the vapor of NH₃ to plasma to form the vapor of the plasma-treated NH₃;
the TiN layer formed by steps b) through d) having a thickness ranging from approximately 0.5 Angstroms (0.05 nm) to approximately 1.5 Angstroms (0.15 nm);
the TiN film having a resistivity between approximately 100 μΩ·cm to approximately 1,000 μΩ·cm; and
the TiN film comprising between approximately 0 atomic percent to approximately 10 atomic percent of C; and between approximately 0 atomic percent to approximately 10 atomic percent of O.

### BRIEF DESCRIPTION OF THE DRAWINGS

For a further understanding of the nature and objects of the present invention, reference should be made to the following detailed description, taken in conjunction with the accompanying drawings, wherein:

FIG. 1 is a graph comparing the TiN film growth rate in angstroms per cycle versus TiMe₅Cp(NMe₂)₃ pulse length in seconds between plasma enhanced depositions at substrate temperatures of 300° C. and 350° C. and non-plasma enhanced depositions at a substrate temperature of 350° C.;

FIG. 2 is a graph comparing the TiN film resistivity in μΩ·cm versus TiMe₅Cp(NMe₂)₃ pulse length in seconds between plasma enhanced depositions at substrate temperatures of 300° C. and 350° C. and non-plasma enhanced depositions at a substrate temperature of 350° C.;

FIG. 3a is a graph showing the percent atomic concentration of components in the TiN film versus Auger Electron Spectroscopy (AES) depth profiling sputter time in minutes for a 5 second TiMe₅Cp(NMe₂)₃ pulse length in plasma mode;

FIG. 3b is a graph showing the percent atomic concentration of components in the TiN film versus sputter time in minutes for a 10 second TiMe₅Cp(NMe₂)₃ pulse length in plasma mode;

FIG. 3c is a graph showing the percent atomic concentration of components in the TiN film versus sputter time in minutes for a 20 second TiMe₅Cp(NMe₂)₃ pulse length in plasma mode;

FIG. 3d is a graph showing the percent atomic concentration of components in the TiN film versus sputter time in minutes for a 10 second TiMe₅Cp(NMe₂)₃ pulse length in non-plasma mode; and

FIG. 3e is a graph comparing the percent atomic concentration of components in the TiN film versus element for the plasma and non-plasma processes.

### DETAILED DESCRIPTION OF PREFERRED EMBODIMENTS

Disclosed are vapor deposition methods, preferably plasma enhanced atomic layer deposition (PEALD) or plasma pulse chemical vapor deposition (P-CVD), to deposit TiN films using at least one titanium-containing precursor selected from the group consisting of Ti(iPr₃Cp)(NMe₂)₃, Ti(iPr₃Cp)(NEt₂)₃, Ti(iPr₃Cp)(NMeEt)₃, Ti(tBu₃Cp)(NMe₂)₃, Ti(tBu₃Cp)(NEt₂)₃, Ti(tBu₃Cp)(NMeEt)₃, Ti(Me₄EtCp)(NMe₂)₃, Ti(Me₄EtCp)(NEt₂)₃, Ti(Me₄EtCp)(NMeEt)₃, Ti(Me₅Cp)(NMe₂)₃, Ti(Me₅Cp)(NEt₂)₃, and Ti(Me₅Cp)(NMeEt)₃.

Applicants believe that the multi-substituted cyclopentadienyl ligands provide molecules exhibiting good thermal stability and a higher decomposition temperature than cyclopentadienyl ligands having less substitutions. Both of these properties allow for a larger vapor deposition process temperature window. Additionally, multiple substitutions on the cyclopentadienyl ligands may help prevent and/or reduce the polymerization/dimerization that occurs with the use of less substituted cyclopentadienyl ligands. This effect may help produce films having less carbon content.

In one alternative, the Ti(iPr₃Cp)(NMe₂)₃, Ti(iPr₃Cp)(NEt₂)₃, and Ti(iPr₃Cp)(NMeEt)₃ precursors are preferred because of expected lower melting points. In a separate alternative, the Ti(Me₅Cp)(NMe₂)₃, Ti(Me₅Cp)(NEt₂)₃, and Ti(Me₅Cp)(NMeEt)₃ precursors are preferred because of higher thermal stability and lower impurity incorporation into the resulting film. In another alternative, the Ti(tBu₃Cp)(NMe₂)₃, Ti(tBu₃Cp)(NEt₂)₃, and Ti(tBu₃Cp)(NMeEt)₃ precursors are preferred because of an expected higher stability than Ti(iPr₃Cp)(NMe₂)₃, Ti(iPr₃Cp)(NEt₂)₃, and Ti(iPr₃Cp)(NMeEt)₃. In another alternative, the Ti(Me₄EtCp)(NMe₂)₃, Ti(Me₄EtCp)(NEt₂)₃, and Ti(Me₄EtCp)(NMeE03 precursors are preferred because of expected lower melting point than Ti(Me₅Cp)(NMe₂)₃, Ti(Me₅Cp)(NEt₂)₃, and Ti(Me₅Cp)(NMeEt)₃. Preferably, the titanium-containing precursor is Ti(Me₅Cp)(NMe₂)₃ and/or Ti(iPr₃Cp)(NMe₂)₃.

The disclosed titanium-containing precursors exhibit sufficient volatility, low melting point, and/or sufficient thermal stability at temperatures relevant for the disclosed methods, Additionally, the disclosed titanium-containing precursors do not contain chlorine and therefore will not produce chlorine or chlorinated by-products when used in the disclosed methods.

The disclosed methods enable deposition of TiN-based films with controlled thickness and composition. The disclosed methods allow for vapor deposition of conduction TiN films at moderate temperatures (below 500° C.). The disclosed methods are useful in the manufacture of semiconductor, photovoltaic, LCD-TFT, or flat panel type devices.

The disclosed methods include: a) providing a reactor having at least one substrate disposed therein; b) introducing into the reactor a vapor of at least one of the disclosed titanium-containing precursors; c) depositing at least part of the at least one titanium-containing precursor onto the at least one substrate to form a titanium-containing layer on the substrate; d) reacting the titanium-containing layer with a vapor of at least one plasma-treated reactant to form a TiN layer on the at least one substrate; and e) optionally repeating steps b) through d) until the TiN film having a desired thickness is obtained.

The titanium-containing precursor is introduced into a reactor in vapor form. The titanium-containing precursor may be fed in liquid state to a vaporizer where it is vaporized before it is introduced into the reactor. Prior to its vaporization, the titanium-containing precursor may optionally be mixed with one or more solvents. The solvents may be selected from the group consisting of toluene, ethyl benzene, xylene, mesitylene, decane, dodecane, octane, hexane, pentane, or others. The resulting concentration may range from approximately 0.05 M to approximately 2 M.

Alternatively, the titanium-containing precursor may be vaporized by passing a carrier gas into a container containing the titanium-containing precursor or by bubbling the carrier gas into the titanium-containing precursor. The titanium-containing precursor may optionally be mixed in the container with one or more solvents. The carrier gas and titanium-containing precursor are then introduced into the reactor as a vapor. The carrier gas may include, but is not limited to, Ar, He, N₂,and mixtures thereof. Bubbling with a carrier gas may also remove any dissolved oxygen present in the precursor solution.

If necessary, the container may be heated to a temperature that permits the titanium-containing precursor to be in its liquid phase and to have a sufficient vapor pressure. The container may be maintained at temperatures in the range of, for example, 0° C. to 150° C. Those skilled in the art recognize that the temperature of the container may be adjusted in a known manner to control the amount of titanuim-containing precursor vaporized.

The vapor of the titanium-containing precursor may be introduced into the reactor for a time period ranging from approximately 0.01 seconds to approximately 60 seconds, alternatively from approximately 5 seconds to approximately 25 seconds, alternatively from approximately 10 seconds to approximately 20 seconds.

At least part of the disclosed titanium-containing precursors is deposited to form a titanium-containing layer using vapor deposition. The temperature and the pressure within the reactor and the temperature of the substrate are held at conditions suitable for vapor deposition of at least part of the titanium-containing precursor onto the substrate. The reactor or deposition chamber may be a heated vessel which has at least one or more substrates disposed within it. The reactor has an outlet which may be connected to a vacuum pump to allow by-products to be removed from the reactor, or to allow the pressure within the reactor to be modified or regulated. Examples of reactors include, without limitation, a parallel-plate type reactor, a cold-wall type reactor, a hot-wall type reactor, a single-wafer reactor, a multi-wafer reactor, a direct plasma reactor, or other types of deposition systems under conditions suitable to cause the precursors to react and form the layers.

The temperature in the reactor is normally maintained at a suitable temperature for the deposition process which is to be performed. The temperature may be maintained between approximately 50° C. and approximately 600° C., preferably between approximately 100° C. to approximately 500° C., and preferably approximately 200° C. to approximately 400° C. The reactor may be maintained at a lower temperature when the substrates themselves are heated directly.

The pressure in the deposition chamber is maintained at a pressure between approximately 0.0001 Torr (0.0133 Pa) to approximately 1000 Torr (133.3 kPa), and preferably between approximately 0.01 Torr (1.33 Pa) to approximately 100 Torr (13.3 kPa).

Generally, the reactor contains one or more substrates onto which the thin films will be deposited. For example, the reactor may contain from 1 to 200 silicon wafers having from 25.4 mm to 450 mm diameters. The substrates may be any suitable substrate used in semiconductor, photovoltaic, flat panel, or LCD-TFT device manufacturing. The substrates may contain one or more additional layers of materials, which may be present from a previous manufacturing step. Dielectric and conductive layers are examples of these. Within the scope of this application, all of the substrate and any layers deposited on the substrate are collectively included within the term substrate. Examples of suitable substrates include without limitation, metal substrates, metal nitride substrates, silicon substrates, silica substrates, silicon nitride substrates, silicon oxynitride substrates, tungsten substrates, and combinations thereof. Additionally, substrates comprising tungsten or noble metals (e.g. platinum, palladium, rhodium, or gold) may be used. Preferably, the substrate is a metal film or metal nitride film.

The substrate may be heated to a sufficient temperature to obtain the desired titanium-containing film at a sufficient growth rate and with desired physical state and composition. Devices used to heat the substrate are known in the art. A non-limiting exemplary temperature range to which the substrate may be heated includes from approximately 50° C. to approximately 600° C., preferably between approximately 100° C. and approximately 500° C., and more preferably between approximately 200° C. and approximately 400° C. However, as explained in the Example, a lower temperature range may be desired to produce films having high conformality and step coverage, such as approximately 100° C. to approximately 300° C. Alternatively, for rapid deposition of TiN films, the temperature range may range from approximately 350° C. to approximately 500° C.

The titanium-containing layer is reacted with the vapor of at least one plasma-treated reactant. The reactant may be a reducing agent selected from the group consisting of N₂, NH₃, Si(NEt₂)₂H₂, N₂H₄, N(SiH₃)₃, NMeH₂, NEtH₂, NMe₂H, NEt₂H, NMe₃, NEt₃, (SiMe₃)₂NH, MeHNNH₂, Me₂NNH₂, phenyl hydrazine, and mixtures thereof. Preferably, the reactant is NH₃. The reactant may be provided in a pure state or diluted with another gas. Suitable diluent gases include an inert gas such as nitrogen, argon, helium, and mixtures thereof.

The vapor of the at least one plasma-treated reactant may be introduced into the reactor for a time period ranging from approximately 0.01 seconds to approximately 10 seconds, alternatively from approximately 0.3 seconds to approximately 5 seconds, and alternatively from approximately 0.5 seconds to approximately 2 seconds.

The reactant is treated by plasma in order to decompose the reactant into its radical form. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

For example, the reactant may be introduced into a direct plasma reactor, which generates a plasma in the reactor, to produce the plasma-treated reactant in the reactor. Exemplary direct plasma reactors include the Titan™ PECVD System produced by Trion Technologies. The reactant may be introduced and held in'the reactor prior to plasma processing. Alternatively, the plasma processing may occur simultaneously with the introduction of reactant. In-situ plasma is typically a 13.56 MHz RF capacitively coupled plasma that is generated between the showerhead and the substrate holder. The substrate or the showerhead may be the powered electrode depending on whether positive ion impact occurs. Typical applied powers in in-situ plasma generators are from approximately 100 W to approximately 1000 W. The disassociation of the reactant using in-situ plasma is typically less than achieved using a remote plasma source for the same power input and is therefore not as efficient in reactant disassociation as a remote plasma system, which may be beneficial for the deposition of TiN on substrates easily damaged by plasma.

Alternatively, the plasma-treated reactant may be produced outside of the reactor. The MKS Instruments' ASTRON®i reactive gas generator may be used to treat the reactant prior to passage into the reactor. Operated at 2.45 GHz, 7kW plasma power, and a pressure ranging from approximately 3 Torr to approximately 10 Torr, the reactant NF₃ may be decomposed into three F⁻ radicals with more than 96% decomposing efficiency. Preferably, the remote plasma may be generated with a power ranging from about 1 kW to about 10 kW, more preferably from about 2.5 kW to about 7.5 kW.

An inert gas purge may be introduced between introduction of the precursor and introduction of the reducing agent. Suitable inert gases include nitrogen, argon, helium, etc.

The vapor deposition conditions within the chamber allow the plasma-treated reactant and the titanium-containing layer to react and form a TiN layer on the substrate. TiN layer thicknesses from approximately 0.5 angstroms (0.005 nm) to approximately 1.5 angstrom (0.15 nm) have been obtained using the disclosed methods. Depending upon the desired thickness of the final TiN film, the process may optionally be repeated. The resulting TiN film exhibits excellent resistivity and low atomic concentrations of C and O.

### EXAMPLES

The following non-limiting examples are provided to further illustrate embodiments of the invention. However, the examples are not intended to be all inclusive and are not intended to limit the scope of the inventions described herein.

### Example—TiN Depositions using Ti(Me₅Cp)(NMe₂)₃ and NH₃

TiN films were obtained using plasma enhanced and non-plasma enhanced vapor deposition methods with Ti(Me₅Cp)(NMe₂)₃ and ammonia. The experiments were performed using a 6′ direct plasma tool (Quros). The Ti(Me₅Cp)(NMe₂)₃ precursor was stored in a canister, heated at 100° C. The lines were heated at 120° C. to prevent condensation. The delivery set-up enables alternate introductions of the vapors of the Ti(Me₅Cp)(NMe₂)₃ precursor and of ammonia (radical species generated by the plasma source for plasma enhanced depositions, no radical species generated in non-plasma enhanced depositions). The pressure in the chamber was set at approximately 1 Torr (133.3 Pa). The shower head was heated at 130° C., as well as the walls of the deposition chamber. The substrate was heated to 300° C. or 350° C. One liter (1 L) of N₂ was used as a dilution gas. Fifty (50) sccm of ammonia (NH₃) were introduced into the reactor during the reactant pulse.

As described in the accompanying figures, the Ti(Me₅Cp)(NMe₂)₃ precursor pulse time was varied. The Ti(Me₅Cp)(NMe₂)₃ precursor pulse was followed by a 20 second argon purge. A 5 second NH₃ pulse was followed by a 2 second argon purge. In the plasma enhanced processes, the NH₃ was treated by 200 W plasma to generate radical species, whereas no plasma treatment occurred in the non-plasma process. The four step process was repeated until the desired TiN film thickness was obtained.

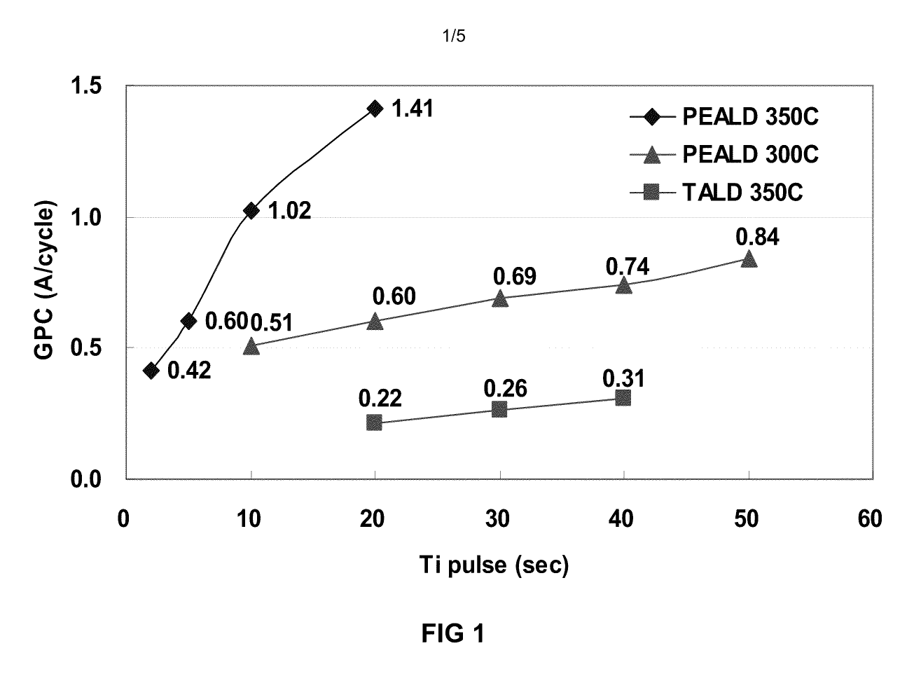

FIG. 1 is a graph comparing the TiN film growth rate in Angstroms per cycle versus TiMe₅Cp(NMe₂)₃ pulse length in seconds between plasma enhanced depositions at substrate temperatures of 300° C. and 350° C. and non-plasma enhanced depositions at a substrate temperature of 350° C. 1 Angstrom=0.1 nanometers. The growth rate for the same Ti(Me₅Cp)(NMe₂)₃ precursor pulse length (i.e,, 20 seconds) using plasma at 300° C. is over twice as fast as the growth rate without plasma at 350° C. The growth rate Ti(Me₅Cp)(NMe₂)₃ precursor pulse length (i.e., 20 seconds) using plasma at 350° is almost seven times faster than the growth rate without plasma at 350° C.

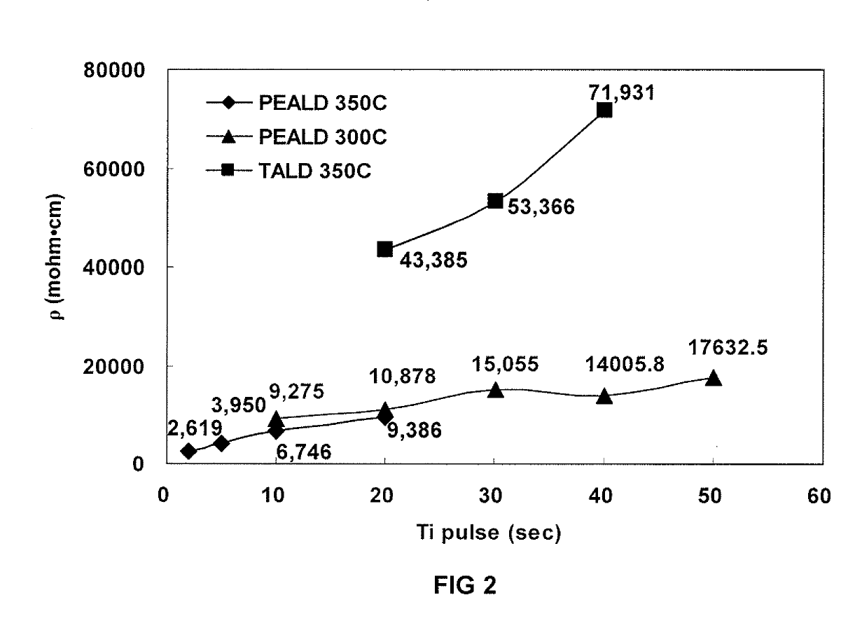

FIG. 2 is a graph comparing the TiN film resistivity in μΩ·cm versus TiMe₅Cp(NMe₂)₃ pulse length in seconds between plasma enhanced depositions at substrate temperatures of 300° C. and 350° C. and non-plasma enhanced depositions at a substrate temperature of 350° C. The TiN film resistivity results drop drastically when the TiN film is produced with plasma. Additionally, improvements are expected to these initial test results with process optimization of the plasma time, plasma power, and/or pulse duration. Applicants believe that process optimization will result in TiN films having a resistivity ranging from approximately 100 μΩ·cm to approximately 1,000 μΩ·cm.

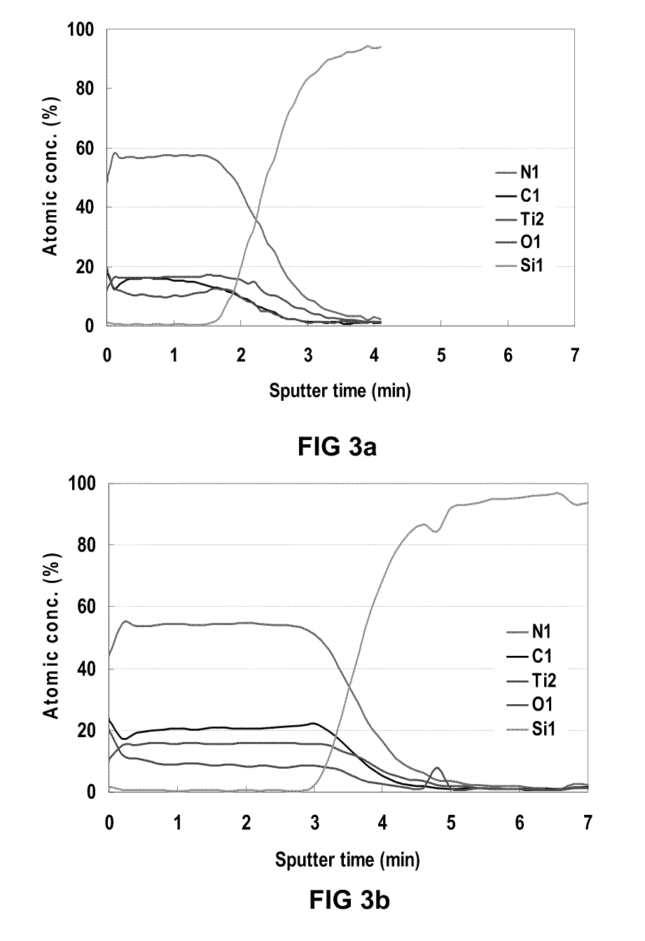

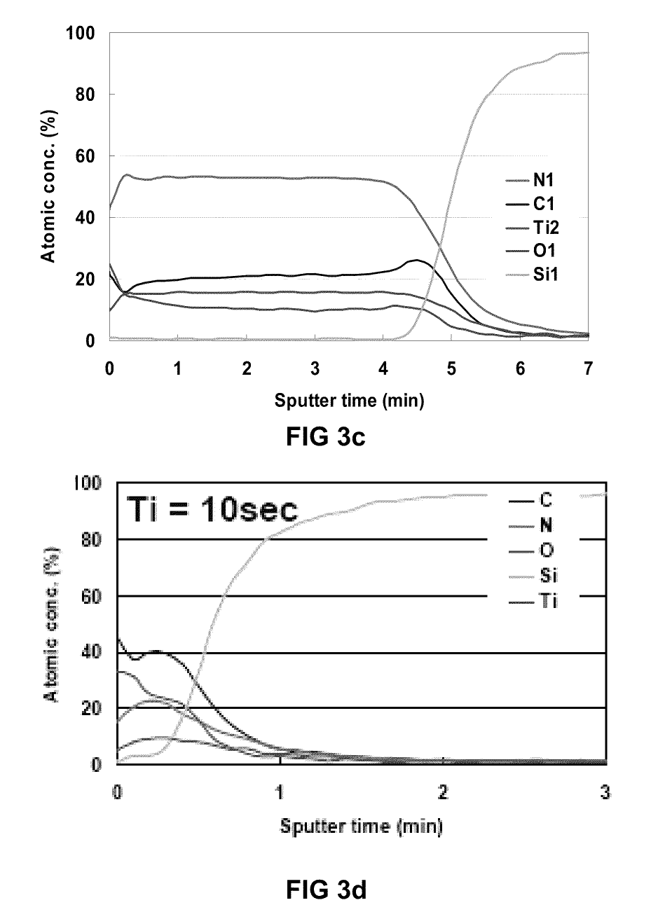

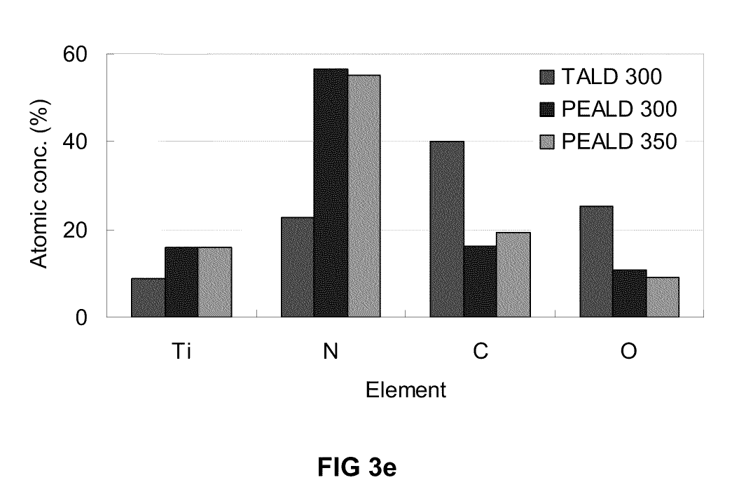

The Auger Electron Spectroscopy (AES) sputter technique was used to determine the composition of the resulting TiN films. FIG. 3a is a graph showing the percent atomic concentration of components in the TiN film versus Auger Electron Spectroscopy (AES) depth profiling sputter time in minutes for a 5 second TiMe₅Cp(NMe₂)₃ pulse length in plasma mode. FIG. 3b is a graph showing the percent atomic concentration of components in the TiN film versus sputter time in minutes for a 10 second TiMe₅Cp(NMe₂)₃ pulse length in plasma mode. FIG. 3c is a graph showing the percent atomic concentration of components in the TiN film versus sputter time in minutes for a 20 second TiMe₅Cp(NMe₂)₃ pulse length in plasma mode. FIG. 3d is a graph showing the percent atomic concentration of components in the TiN film versus sputter time in minutes for a 10 second TiMe₅Cp(NMe₂)₃ pulse length in non-plasma mode. FIG. 3e is a graph comparing the percent atomic concentration of components in the TiN film versus element for the non-plasma and plasma processes. The TiN films resulting from the plasma processes contain more Ti and N and less C and O than the TiN films resulting from the non-plasma process. Reductions in the C and O levels are also expected with process optimization of the plasma time, plasma power, and/or pulse duration. Applicants believe that process optimization will result in TiN films having a oxygen and carbon content ranging from approximately 0 atomic % to approximately 10 atomic %, preferably from approximately 0 atomic % to approximately 5 atomic %.

Although set up as Atomic Layer Deposition (ALD) processes, the high deposition rates at 350° C. for the plasma enhanced process suggest that the ALD characteristic of self-limiting thickness per cycle may not be occurring. The 350° C. plasma enhanced process also produced TiN film having a slight increase in C content compared to those produced by the 300° C. plasma process. Both of these outcomes may indicate partial decomposition of the TiMe₅Cp(NMe₂)₃ precursor. However, as the plasma process at 350° C. produces a TiN film at a high deposition rate with a decrease in resistivity and C and O oxygen content as compared to thermal ALD, the plasma process at 350° C. may be useful for the rapid deposition of TiN films. Alternatively, when high conformality and step coverage is required, the 300° C. process may be beneficial.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A vapor deposition method for depositing a TiN film onto at least one substrate, the method comprising the steps of:
a) providing a reactor having at least one substrate disposed therein;
b) introducing into the reactor a vapor of at least one titanium-containing precursor selected from the group consisting of Ti(iPr₃Cp)(NMe₂)₃, Ti(iPr₃Cp)(NEt₂)₃, Ti(iPr₃Cp)(NMeEt)₃, Ti(tBu₃Cp)(NMe₂)₃, Ti(tBu₃Cp)(NEt₂)₃, Ti(tBu₃Cp)(NMeEt)₃, Ti(Me₄EtCp)(NMe₂)₃, Ti(Me₄EtCp)(NEt₂)₃, Ti(Me₄EtCp)(NMeEt)₃, Ti(Me₅Cp)(NMe₂)₃, Ti(Me₅Cp)(NEt₂)₃, and Ti(Me₅Cp)(NMeEt)₃;
c) depositing at least part of the at least one titanium-containing precursor onto the at least one substrate to form a titanium-containing layer on the at least one substrate;
d) reacting the titanium-containing layer with a vapor of at least one plasma-treated reactant to form a TiN layer on the at least one substrate; and
e) optionally repeating steps b) through d) until the TiN film having a desired thickness is obtained.

2. The method of claim 1, wherein the at least one plasma-treated reactant is a reducing agent selected from the group consisting of N₂, NH₃, Si(NEt₂)₂H₂, N₂H₄, N(SiH₃)₃, NMeH₂, NEtH₂, NMe₂H, NEt₂H, NMe₃, NEt₃, (SiMe₃)₂NH, MeHNNH₂, Me₂NNH₂, phenyl hydrazine, and mixtures thereof.

3. The method of claim 1, wherein at least one substrate has a temperature between approximately 50° C. and approximately 600° C.

4. The method of claim 1, wherein the reactor has a pressure between approximately 0.0001 Torr (0.0133 Pa) and approximately 1000 Torr (133.3 kPa).

5. The method of claim 1, wherein:
the reactor is a direct plasma reactor; and
the vapor of the at least one plasma-treated reactant is produced by introducing a vapor of a reactant into the direct plasma reactor and exposing the vapor of the reactant to plasma to form the vapor of the plasma-treated reactant.

6. The method of claim 1, wherein the at least one titanium-containing precursor is selected from the group consisting of Ti(iPr₃Cp)(NMe₂)₃, Ti(iPr₃Cp)(NEt₂)₃, Ti(iPr₃Cp)(NMeEt)₃, and mixtures thereof.

7. The method of claim 1, wherein the at least one titanium-containing precursor is selected from the group consisting of Ti(Me₅Cp)(NMe₂)₃, Ti(Me₅Cp)(NEt₂)₃, Ti(Me₅Cp)(NMeEt)₃, and mixtures thereof.

8. The method of claim 1, wherein the at least one titanium-containing precursor is selected from the group consisting of Ti(tBu₃Cp)(NMe₂)₃, Ti(tBu₃Cp)(NEt₂)₃, Ti(tBu₃Cp)(NMeEt)₃, and mixtures thereof.

9. The method of claim 1, wherein the at least one titanium-containing precursor is selected from the group consisting of Ti(Me₄EtCp)(N Me₂)₃, Ti(Me₄EtCp)(NEt₂)₃, Ti(Me₄EtCp)(NMeEt)₃, and mixtures thereof.

10. A vapor deposition method for depositing a TiN film onto at least one substrate, the method comprising the steps of:
a) providing a reactor having at least one substrate disposed therein;
b) introducing into the reactor a vapor of Ti(Me₅Cp)(NMe₂)₃;
c) depositing at least part of Ti(Me₅Cp)(NMe₂)₃ onto the at least one substrate to form a titanium-containing layer on the at least one substrate;
d) reacting the titanium-containing layer with a vapor of plasma-treated NH₃ to form a TiN layer on the at least one substrate; and
e) optionally repeating steps b) through d) until the TiN film having a desired thickness is obtained.

11. The method of claim 1, wherein:
the reactor is a direct plasma reactor; and
the vapor of plasma-treated NH₃ is produced by introducing a vapor of NH₃ into the direct plasma reactor and exposing the vapor of NH₃ to plasma to form the vapor of the plasma-treated NH₃.

12. The method of claim 11, wherein the TiN layer formed by steps b) through d) has a thickness ranging from approximately 0.5 Angstroms (0.05 nm) to approximately 1.5 Angstroms (0.15 nm).

13. The method of claim 10, wherein the TiN film has a resistivity between approximately 100 μΩ·cm to approximately 1,000 μΩ·cm.

14. The method of claim 10, wherein the TiN film comprises between approximately 0 atomic percent to approximately 10 atomic percent of C;
and between approximately 0 atomic percent to approximately 10 atomic percent of O.
